(19) United States
(12) Patent Application Publication
(10) Pub. No.: US 2026/0017438 A1
(43) Pub. Date: Jan. 15, 2026

(54) METHOD FOR OPTIMIZING WELL PLACEMENT FOR A HYDROCARBON RESERVOIR UTILIZING AN OPTIMIZATION ALGORITHM AND INTEGRATING MULTIPLE CONSTRAINTS

(71) Applicant: SAUDI ARABIAN OIL COMPANY, Dhahran (SA)

(72) Inventor: Sharif Mohamed SHALABY, Dhahran (SA)

(73) Assignee: SAUDI ARABIAN OIL COMPANY, Dhahran (SA)

(21) Appl. No.: 18/769,723

(22) Filed: Jul. 11, 2024

(51) Int. Cl. G06F 30/28; E21B 41/00

(52) U.S. Cl. CPC G06F 30/28; E21B 41/00; E21B 2200/20

(57) ABSTRACT

System and methods are disclosed relating to field development planning and well drilling in the petroleum industry, and more specifically, to optimizing the placement of hydrocarbon wells utilizing an optimization algorithm and integrating multiple parameters and constraints. This method includes receiving multiple parameters and constraints as input, executing an optimization algorithm simulation with different well locations, performing dynamic simulations across all existing wells in all models, running an anti-collision algorithm to check for collision with existing trajectories inside and outside the reservoirs, and reiterating the aforementioned steps to maximize the net present value of the parameters and yield an optimal well count and location that honor the multitude of constraints.

### FIELD OF THE DISCLOSURE

This disclosure relates generally to field development planning and well drilling in the petroleum industry, and more specifically, to optimizing well placement for a hydrocarbon reservoir utilizing an optimization algorithm and integrating multiple parameters and constraints.

### BACKGROUND OF THE DISCLOSURE

In the oil industry, well placement is a process to improve oil recovery by drilling newer wells in a hydrocarbon reservoir. Drilling new wells is a highly challenging yet vital task in oil field development. Optimal well locations are rarely known and difficult to quantify due to the complexity of reservoir and depletion situations as well as the vastly varying conditions applying to each oil field. Complex subsurface reservoirs are often described by numerical models that use uncertain data, a task that is quite challenging. Multiple subsurface models are usually constructed to capture the uncertainty of the data, so when these models are used, their predictions are spread enough to cover the range of possible outcomes. Furthermore, there exist numerous logistical factors that influence optimal well location. There are a large number of variables and mass quantities of data to consider when planning wellbore and oil field development operations. It is often useful to model or simulate the parameters and behavior of an oil field development operation to determine an optimal or desired plan.

Optimization algorithms are a class of algorithms that aim to find a set of possible solutions to a given problem by finding optimal parameters that minimizes or maximizes a given objective function. In the oil industry, such an algorithm may be used to determine well placement that maximizes a desired parameter. However, existing optimization processes and systems in the industry exist as independent tools used for individual tasks by the various disciplines involved in the planning process. Other processes involve many iterations between reservoir management engineers, geologists and drillings to propose just a few wells to be drilled. The need for many interdependent iterations is the lack of a comprehensive tool to consider all the constraints. Existing optimization processes fail to supply a holistic approach honoring the requirements from many disciplines in a one-stop shop for well planning.

In an environment where increasingly difficult wells of higher value are being drilled in increasingly complex reservoirs with fewer resources, there is a need for a rapid and complete well planning, cost, and risk assessment and collision-avoidance tool. A systematic and automated process is needed to streamline the integration between the different disciplines involved in the well placement process by using the outcomes of multiple scenarios to explore uncertainty and help make informed decisions on future well targets.

### SUMMARY OF THE DISCLOSURE

Various details of the present disclosure are hereinafter summarized to provide a basic understanding. This summary is not an extensive overview of the disclosure and is neither intended to identify certain elements of the disclosure nor to delineate the scope thereof. Rather, the primary purpose of this summary is to present some concepts of the disclosure in a simplified form prior to the more detailed description that is presented hereinafter.

According to an embodiment consistent with the present disclosure, a method for optimizing well placement for a hydrocarbon reservoir includes receiving a set of parameters and constraints as input; executing an optimization algorithm upon the set of constraints to initiate a set of dynamic simulations wherein the dynamic simulations capture multiple realizations, to test a plurality of different well locations to produce a first set of outcomes corresponding to well count and well locations; evaluating the first set of outcomes; executing multiple iterations of the dynamic simulations and evaluating each corresponding set of outcomes until a desired outcome is achieved; and executing an anti-collision algorithm wherein the algorithm checks for potential collisions with one or more existing trajectories inside and outside the hydrocarbon reservoir.

According to another embodiment, a computer-readable storage medium containing instructions for optimizing well placement for a hydrocarbon reservoir is disclosed, wherein the instructions, when executed by a processor, cause the processor to perform operations including receiving a set of parameters and constraints as input; executing an optimization algorithm upon the set of constraints to initiate a set of dynamic simulations wherein the dynamic simulations capture multiple realizations, to test a plurality of different well locations to produce a first set of outcomes corresponding to well count and well locations; evaluating the first set of outcomes; executing multiple iterations of the dynamic simulations and evaluating each corresponding set of outcomes until a desired outcome is achieved; and executing an anti-collision algorithm wherein the algorithm checks for potential collisions with one or more existing trajectories inside and outside the hydrocarbon reservoir.

Any combinations of the various embodiments and implementations disclosed herein can be used in a further embodiment, consistent with the disclosure. These and other aspects and features can be appreciated from the following description of certain embodiments presented herein in accordance with the disclosure and the accompanying drawings and claims.

### BRIEF DESCRIPTION OF THE DRAWINGS

FIG. 1 is a flowchart diagram depicting an example of a method for optimizing well placement for a hydrocarbon reservoir utilizing an optimization algorithm and integrating multiple parameters and constraints.

FIG. 2 is a diagram depicting an example of a workflow for optimizing well placement for a hydrocarbon reservoir and details various elements involved in the well placement optimization workflow, according to at least one embodiment.

FIG. 3 is a graphical diagram depicting an example of an incremental value analysis between wells that may be provided for the cost model and objective function, according to at least one embodiment.

FIG. 4. is a graphical diagram depicting an example of a creaming curve representing an optimal number of wells according to the cost model and objective function, according to at least one embodiment.

FIG. 5. is a diagram depicting an example of a proximity analysis of adjacent well trajectories provided for the anti-collision algorithm, according to at least one embodiment.

FIG. 6. is a diagram depicting an example of a densely congested pad where anti-collision risk management via an anti-collision algorithm is paramount to a comprehensive planning workflow, according to at least one embodiment.

FIG. 7 is a diagram depicting an example of a top-down view of an oil field schematic, where the method allows for the planning of well placement while honoring parameters and constraints such as faults, contact with other areas, existing wells, and surface pad locations, according to at least one embodiment.

FIG. 8 is a diagram depicting an example of a topographical map of proposed well locations presented by numerous bubbles resulting from running several iterations of the optimization algorithm, according to at least one embodiment.

FIG. 9 depicts an example computing environment that can be used to perform methods according to an aspect of the present disclosure.

FIG. 10 depicts a cloud computing environment that can be used to perform one or more actions according to an aspect of the present disclosure.

### DETAILED DESCRIPTION

Embodiments of the present disclosure will now be described in detail with reference to the accompanying Figures. Like elements in the various figures may be denoted by like reference numerals for consistency. Further, in the following detailed description of embodiments of the present disclosure, numerous specific details are set forth in order to provide a more thorough understanding of the claimed subject matter. However, it will be apparent to one of ordinary skill in the art that the embodiments disclosed herein may be practiced without these specific details. In other instances, well-known features have not been described in detail to avoid unnecessarily complicating the description. Additionally, it will be apparent to one of ordinary skill in the art that the scale of the elements presented in the accompanying Figures may vary without departing from the scope of the present disclosure.

Embodiments of the present disclosure relate to field development planning and well drilling in the petroleum industry, and more specifically, to optimizing the placement of hydrocarbon wells utilizing an optimization algorithm and integrating multiple parameters and constraints.

To properly develop oil and gas fields, production and injection wells must be planned in a way that maximizes hydrocarbon recovery. However, well planning optimization is not only about maximizing production of hydrocarbons, it must also maximize the net present value (NPV) for particular field developments since they are heavily impacted by varying price movements and cost factors related to things like the facilities and surface production network. Furthermore, well planning optimization must include consideration of potential collisions with existing trajectories inside and outside the hydrocarbon reservoir and their related risks. The planning workflow must also honor the avoidance areas of surface and subsurface constraints, such as the surface pad location, geo-hazards, and faults. Constraints related to best reservoir management practices, such as offset to certain fluid contacts, are additionally included. To plan and execute a well, multiple data sources and disciplines must be efficiently aligned and integrated.

Existing processes are insufficient in that they lack consideration and integration of all the requirements from the various disciplines of the well placement process. They lack the use of multiple subsurface models that capture inherited subsurface uncertainty, the incorporation of anti-collision analyses with trajectories inside and outside the hydrocarbon reservoir, and optimization based on economic parameters. Conventional processes further lack considerations of optimal well counts, well interferences, and their effect on incremental hydrocarbon production and respective NPV values. Minimizing well placement costs and associated risks requires planning techniques that account for the interdependencies involved in a cohesive oil field development plan. The present disclosure provides a holistic approach to all these interdependent disciplines in one platform.

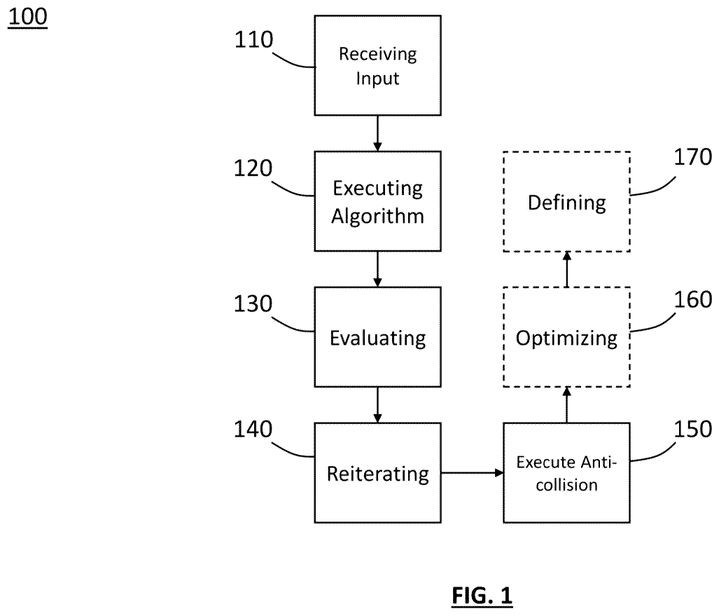

In view of the foregoing structural and functional features described above, an example(s) method will be better appreciated with reference to FIG. 1. While, for purposes of simplicity of explanation, the example method(s) of FIG. 1 is shown and described as executing serially, it is to be understood and appreciated that the present examples are not limited by the illustrated order, as some actions could in other examples occur in different orders, multiple times and/or concurrently from that shown and described herein. Moreover, it is not necessary that all described actions be performed to implement the method(s).

FIG. 1 is a flowchart diagram depicting an example of a method for optimizing the well placement for a hydrocarbon reservoir utilizing an optimization algorithm and integrating multiple parameters and constraints. Method 100 comprises receiving a set of parameters and constraints as input at step 110, executing an optimization algorithm upon the set of parameters and constraints to initiate a set of dynamic simulations wherein the dynamic simulations capture multiple realizations, to test a plurality of different well locations to produce a first set of outcomes corresponding to well count and well locations at step 120, evaluating the first set of outcomes at step 130, executing multiple iterations of the dynamic simulations and evaluating each corresponding set of outcomes until a desired outcome is achieved at step 140, and executing an anti-collision algorithm wherein the algorithm checks for potential collisions with one or more existing trajectories inside and outside the hydrocarbon reservoir at step 150.

In an embodiment, the set of parameters and constraints may also include surface constraints and subsurface constraints. In a further embodiment, a surface constraint may be a surface pad location. A surface pad may be any surface location which houses the wellheads for a number of drilled wells. Such pads allow for widespread underground development by concentrating wellheads at the surface. The set of parameters and constraints received as input may include, but are not limited to, data on well constraints such as type (horizontal or vertical), geometry, length, location, other existing or previously planned wells in the current reservoir of interest or the overlaying shallower reservoirs, geomechanics constraints such as high-risk reservoir areas where stress may be high as well as the potential for losses, data on drilling constraints such as Dog Leg Severity (DLS) and buildup radius, water handling capacity, ullage constraints, cost of drilling and completion data, and water production and injection attributes. A Dog Leg Severity may be a normalized estimate of the overall curvature of an actual well path between two consecutive directional survey stations, according to the minimum curvature survey calculation method. For example, a DLS is typically calculated in degrees/100 ft.

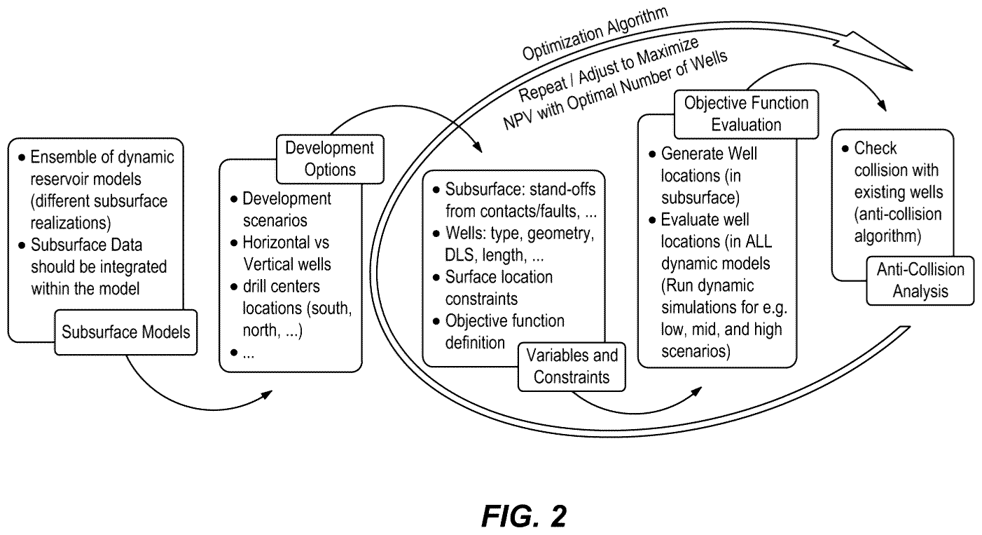

In an embodiment, the set of parameters and constraints may also include multiple subsurface static models as part of the input to capture inherited subsurface uncertainty. A subsurface static model may be any model which integrates static subsurface properties such as well logs, rock properties, fluid properties, etc. For example, a static model of a reservoir may be a three-dimensional representation of the geological structure, facies, and petrophysical properties of the reservoir. Static models may be used to estimate the volume and distribution of the hydrocarbons in the reservoir, the connectivity, and pressure and saturation conditions. In certain embodiments, the set of parameters and constraints may also include multiple subsurface dynamic models as input. A subsurface dynamic model may be any mathematical simulation that integrates the changes in the static properties with time. Dynamic models may be used to forecast performance and recovery under different strategies such as placement, injection, and completion. Conventional workflows use geological basin modeling tools or a basin simulator for characterizing a reservoir by identifying and quantifying reservoir boundaries (such as top and bottom), their geometry, the extent of their zones, pinchouts, and other streaks of high permeability. Conventional simulators may integrate a basin simulator or replace it, but still lack the well count and location optimization for producers and injectors in field development. Conversely, this disclosure may utilize multiple subsurface realizations, such as multiple static model realizations, as input. Each realization may have a different geometry, extent, and connectivity of the reservoir being simulated. For example, with reference to FIG. 2, an ensemble of subsurface models are provided as input before the execution of the optimization algorithm, according to at least one embodiment. These models may include multiple dynamic reservoir models that integrate changes in different subsurface realizations, which themselves integrate aforementioned subsurface data. Furthermore, the present disclosure focuses on optimizing the number of and location of wells in a particular reservoir or field to maximize the Net Present Value (NPV) while considering several dynamic reservoir simulations that evaluate an objective function using the aforementioned static and dynamic model(s) that represent the varying scenarios for things such as the geometry, connectivity, and extent of reservoirs as well as the aforementioned constraints and standoffs all as input for the optimization algorithm. Not only do existing workflows lack the inclusion of multiple models, but also the dynamic nature of the models disclosed herein and their inclusion as input to the optimization algorithm.

An optimization algorithm is executed to initiate a set of dynamic simulations wherein the dynamic simulations capture multiple realizations. Such an algorithm may include any process or set of rules to be followed in calculations or other problem-solving operations. An optimization algorithm may be any algorithm used to find the best possible solution to a given problem. The goal of such an algorithm is generally to find the optimal solution that minimizes or maximizes a given objective function. For example, in the present disclosure, an optimization algorithm is run to maximize the NPV for number and location of wells in a particular reservoir while considering a vast amount of constraints. The disclosed optimization algorithm presents a holistic and comprehensive approach to integrating multiple data sets, constraints, various models, and requirements from different disciplines into one platform. Conventional workflows tackle individual bits and pieces of the well placement process, while the current disclosure presents a one-stop shop for well planning. Other workflows that utilize optimization algorithms attempt to predict oil rates using a machine learning model trained on historical data. Such workflows optimize involving an objective function based on forecasted injection rates and forecasted oil rates. Thus they associate the uncertainty of their forecasted production rates with the uncertainty in the determined preferred operating parameters. Such optimization algorithms do not optimize NPV of production using multiple and differing trajectories and do not consider anti-collision risk management.

In an embodiment, method 100 may further include defining a cost model and objective function, wherein the desired outcome further optimizes economic value through the cost model at step 170. The optimal number and location of wells may also be elected so as to maximize an economic-based cost function. A cost model may be any tool used to analyze the price movements of important cost drivers and monitor their impact on a given commodity. The cost model and objective function may be any model or function which adequately considers the economic factors that influence production efficiency and thus allow for maximizing the production of hydrocarbons.

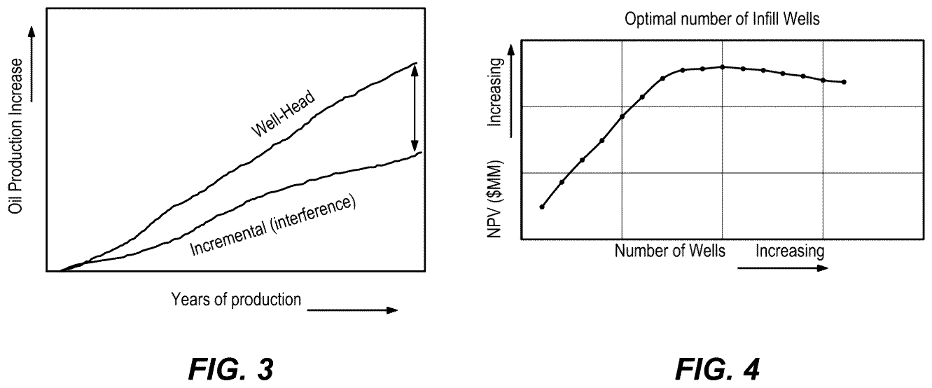

In an embodiment, method 100 may further include optimizing the numbers and locations of production and injection wells based on the outcomes from the dynamic simulations at step 160. For example, interference between wells must always be taken into consideration to determine the incremental value of the well. For example, FIG. 3 depicts an example of an incremental value analysis between wells. Such incremental value via interference between wells may be provided for within the cost model and objective function to maximize the NPV of a proposed well, according to at least one embodiment. Water production must also be considered due to its costs associated with disposal, treatment, storage and the like. Thus, such considerations impact a development's net value.

The cost model and objective function may provide for the NPV of the proposed well to quantify the maximization of its recovery. A net present value generally may provide a method for evaluating and comparing capital projects or financial products with cash flows spread over time, such as loans, investments, or payouts from contracts. NPVs simplicity allows for it to be a useful tool for determining whether a project or investment will result in net profit or net loss. For example, in the present disclosure, NPV may be utilized to quantify the incremental value of a well, or more specifically, how much crude oil may be available for production in the potential reserve. For example, FIG. 4 depicts an example of graphical representation of the relationship between the number of wells and the resulting NPV in $MM, according to an embodiment. NPV optimization may consider any relevant production cost drivers such as but not limited to water cut development, proximity to other wells, and proximity to oil-water contacts-all of which impact the efficiency of production and thus increase or decrease its associated costs or value. An optimal number of wells based on this graph would provide for a maximized NPV according to the provided cost model and objective function. For example, 10 could be the number of wells which corresponds to a maximized NPV of 20 in $MM. Such economic considerations may also be optimized through the dynamic simulations and multiple realization models.

The dynamic simulations initiated by the optimization algorithm may be any computer program used to model the time-varying behavior of a set of dynamic inputs, or a system. Such a system may be described by ordinary or partial differential equations. The equations may be solved through numerical integration methods to produce a transient behavior over a specified period of time. For example, numerical integration methods may include using a fixed step through a set interval, or an adaptive step, or multiple time steps at different points within the simulation model, or any combination thereof. Such a computer program may be run by any computing system or similar device, such as but not limited to, one or more general purpose networked computer systems, embedded computer systems, routers, switches, server devices, client devices, various intermediate devices/nodes, standalone computer systems, or various mobile clients such as, for example, a personal digital assistant (PDA), laptop computer, pager, and the like, provided it includes sufficient processing capabilities.

For example, the dynamic simulations in the present disclosure may capture multiple subsurface realizations. A subsurface realization may be any geological realization consisting of patterns that contain complex geological structures. Generally in previous workflows, engineers use single subsurface realizations which do not properly capture the uncertainties in the subsurface constraints, and use a reference case to evaluate the value of one or more potential well targets. The present disclosure however captures multiple realizations which do incorporate more of the subsurface uncertainty in planning and decision making. These sets of multiple realizations may be of any size or number in order to represent any associated spatial uncertainty. For example, these multiple realizations may be prepared with all existing wells in a given area, according to at least one embodiment.

In at least one embodiment, the multiple realizations may include an ensemble of probability models, or high, mid, and low scenarios, or any combination thereof. While the amount of crude oil available for production in a reservoir cannot be determined exactly, it may be estimated. A probability model may be any method or tool used to calculate the potential production and achieve an estimate of production rates of crude oil for a given reservoir. For example, an ensemble of probability models may include high, mid, or low scenarios, or more specifically, P10/P50/P90 models. Such models estimate the range of uncertainty of the recoverable and/or potentially recoverable volumes by either deterministic scenarios or by a probability distribution. A probability distribution will provide a high, mid, and low estimate such that: there should be at least a 90% probability (P90) that the quantities actually recovered will equal or exceed the low estimate; there should be at least a 50% probability (P50) that the quantities actually recovered will equal or exceed the mid estimate; and there should be at least a 10% probability (P10) that the quantities actually recovered will equal or exceed the high estimate. For example, a geologist's calculation estimates that there is a 90% chance an oil reservoir contains 100 million barrels of crude oil, and another estimate calculates there is a 10% of producing another 40 million barrels in addition to the 100 million barrels. In this scenario, P10 as the highest figure translates that it is possible to produce up to 140 million barrels. P90, as the lowest figure translates that it is proved we can produce up to 100 million barrels.

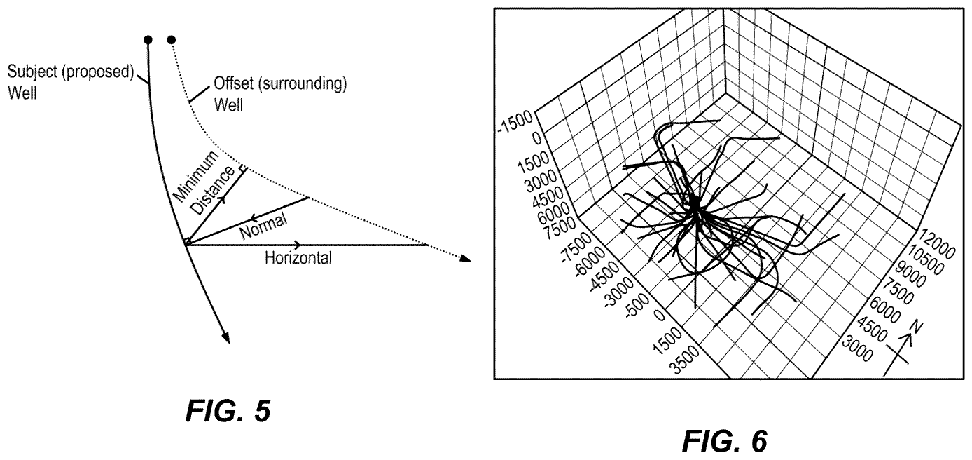

An anti-collision algorithm is executed to check for potential collisions with one or more existing trajectories inside and outside the hydrocarbon reservoir. An anti-collision algorithm may include any process or set of rules to be followed in calculations or other problem-solving operations in order to detect potential collisions with any existing trajectories. An existing trajectory may be any existing subsurface well path or connectivity or the like. A critical concern in directional drilling is ensuring collision avoidance while drilling multi-well scenarios from pad locations. Collision risk is an integral part of the well planning process and must be integrated into a holistic well placement workflow. For example, with reference to FIG. 6, which depicts an example of a densely congested pad where anti-collision risk management via an anti-collision algorithm is paramount to a comprehensive planning workflow, according to at least one embodiment, the existence of several wellbores from one pad demonstrates a very high collision risk at the shallower section. In another embodiment, with reference to FIG. 5, an example of a proximity analysis of adjacent well trajectories that may be included in the anti-collision algorithm is depicted. For example, the anti-collision algorithm may provide for data such as the maximum distance, normal distance, and horizontal distances between a proposed well and an existing offset or surrounding well for avoidance purposes provided by a given proximity analysis, according to an embodiment. Such subsurface analyses may be provided by any of the aforementioned subsurface constraint data sources such as well logs, static models, and the like.

The anti-collision algorithm may present results in a graphic form, such as that provided in FIG. 6, according to an embodiment. Such a graphic representation may provide useful data such as direction and depth and other parameters conveniently provided by a three-dimension subsurface presentation. In another embodiment, the algorithm may simply provide risk data or provide approval or rejection of a given proposed well location depending upon the result's comparison a pre-determined trajectory or collision-risk threshold. A collision may be any direct or indirect contact between trajectories that poses a risk to the overall oil field stability or organization. For example, a collision between a proposed wellbore and an existing wellbore may be a direct breaking of the subsurface boundaries between them, or be within some determined minimum range of risk that varies depending on any geological variables such as surrounding stresses, subsurface composition, water presence, geometry, or the like. Existing trajectories may exist inside or outside the hydrocarbon reservoir or any combination of multiple trajectories thereof. For example, the anti-collision algorithm may consider multiple trajectories within the reservoir, multiple trajectories outside the reservoir, or any other trajectory known within a given radius of the proposed well or surface pad location. Such trajectories may also include those above the reservoir all the way to surface facilities. According to another embodiment, another approach to anti-collision may include avoidance. Avoidance may include the avoiding of other hazard zones, such as geomechanically hazard zones, standoffs from contacts, or faults. Such other hazards to be avoided may be provided by other mechanisms, such as polygonal approaches to define areas. These avoidances may be integrated into the anti-collision process or combined with results from the anti-collision algorithm to define comprehensive subsurface risk reports. An oil-water contact (OWC) may be any bounding surface in a given reservoir or field above which oil predominantly occurs and below which water predominantly occurs. Oil-water contacts may be flat or tilted or in another irregular orientation. Contacts may also include gas-oil contacts or gas-water contacts.

The optimization algorithm is run to test a plurality of different well locations to produce a first set of outcomes corresponding to well count and well locations. Said outcomes may then be evaluated. Evaluation may include any consideration of any individual or combination of the relevant parameters which contribute to optimal well placement. For example, a first set of outcomes for an initially planned well location may produce an extremely lackluster NPV. In another example, a set of outcomes may produce a well that betrays the surface pad location and does presents near a fault or other geo-hazard. The above steps may then be executed reiteratively which each corresponding set of outcomes being evaluated until a desired outcome is achieved. Each step may be reiterated any number of times and in any order. Different proposed well locations as input as well as models or other inputs or any combination thereof may also be adjusted after any corresponding set of outcomes in order to achieve a desired outcome.

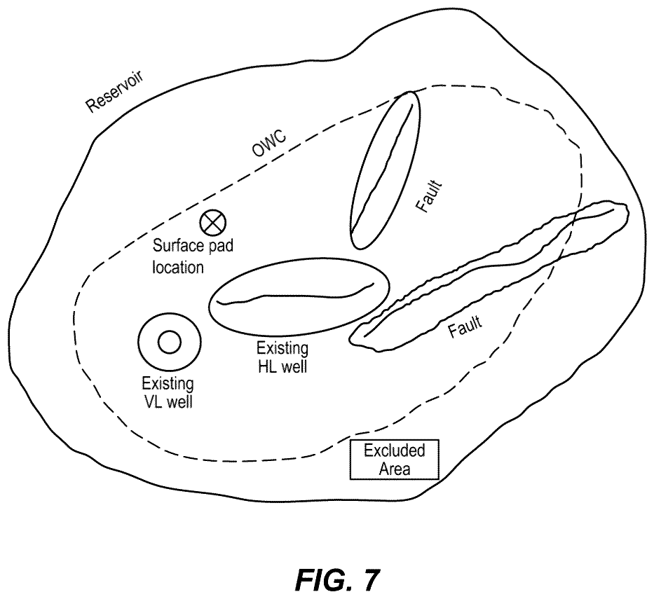

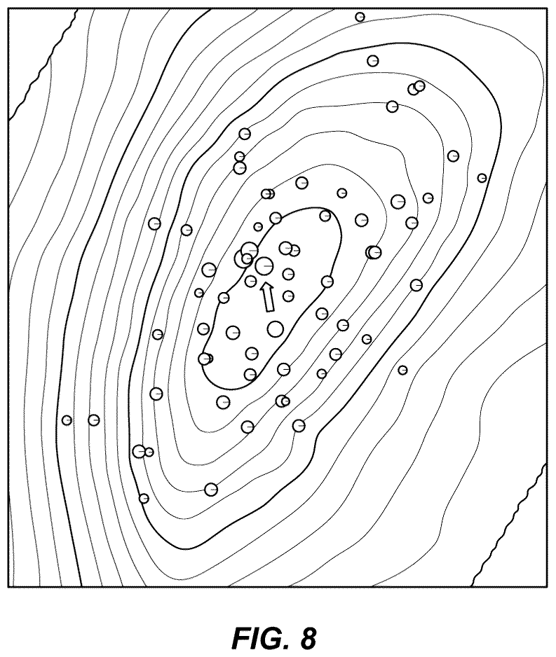

A desired outcome may be any result in which an optimal number and optimal location of wells are reached. The optimal number and optimal location of wells for the desired outcome may be when the development NPV is maximized, the subsurface constraints are honored, such as proximity to geo-hazards or proximity to faults, the surface constraints are honored, such as pad location, and collisions with existing trajectories inside and outside the hydrocarbon reservoir are avoided. For example, FIG. 7 depicts an example of a top-down view of an oil field schematic, where the method allows for the planning of well placement while honoring constraints such as faults, contact with other areas, oil-water contact, existing wells, both horizontal and vertical, and surface pad locations, according to at least one embodiment. In another embodiment, with reference to FIG. 8, a diagram depicting an example of a topographical map of proposed well locations presented by numerous bubbles is shown. The number of bubbles may result from the several iterations of running the numerous dynamic simulations using the optimization algorithm. Bubble size may also represent well NPV. For example, an initially planned well location may be represented by a uniquely-colored dot. In the illustrated example of FIG. 8, there exists a cluster of wells with large bubble size slightly northwest of the initially planned well from which the arrow points. Any number of well placement suggestions may be tested and ran through any number of iterations until the desired outcome is reached. Such a workflow result may suggest reconsideration of the well placement in favor of an area holding higher well NPVs, less resistance from surface and subsurface constraints, and while avoiding collision areas. FIG. 8 exemplifies just one of many ways the results of the disclosed optimization workflow may be presented. Other representations include but are not limited to topographical representations, coordinate-based gridded presentations in two or more dimensions, binary or spectrum-based presentations in response to predetermined thresholds, such as low-risk to high-risk, yes or no to honoring an individual or multiple constraints, and numerical data sets in sheets, tables, or graphs. Outcomes may be presented, shared, or distributed amongst any device or media possessing adequate computing or connectivity capabilities, such as but not limited to mobile cellular devices, smart phones, PDAs, personal computers, standalone desktop computers, computer networks, virtual machines, tablets, or the like.

While the disclosure has described several exemplary embodiments, it will be understood by those skilled in the art that various changes can be made, and equivalents can be substituted for elements thereof, without departing from the spirit and scope of the invention. In addition, many modifications will be appreciated by those skilled in the art to adapt a particular instrument, situation, or material to embodiments of the disclosure without departing from the essential scope thereof. Therefore, it is intended that the invention not be limited to the particular embodiments disclosed, or to the best mode contemplated for carrying out this invention, but that the invention will include all embodiments falling within the scope of the appended claims. Moreover, reference in the appended claims to an apparatus or system or a component of an apparatus or system being adapted to, arranged to, capable of, configured to, enabled to, operable to, or operative to perform a particular function encompasses that apparatus, system, or component, whether or not it or that particular function is activated, turned on, or unlocked, as long as that apparatus, system, or component is so adapted, arranged, capable, configured, enabled, operable, or operative.

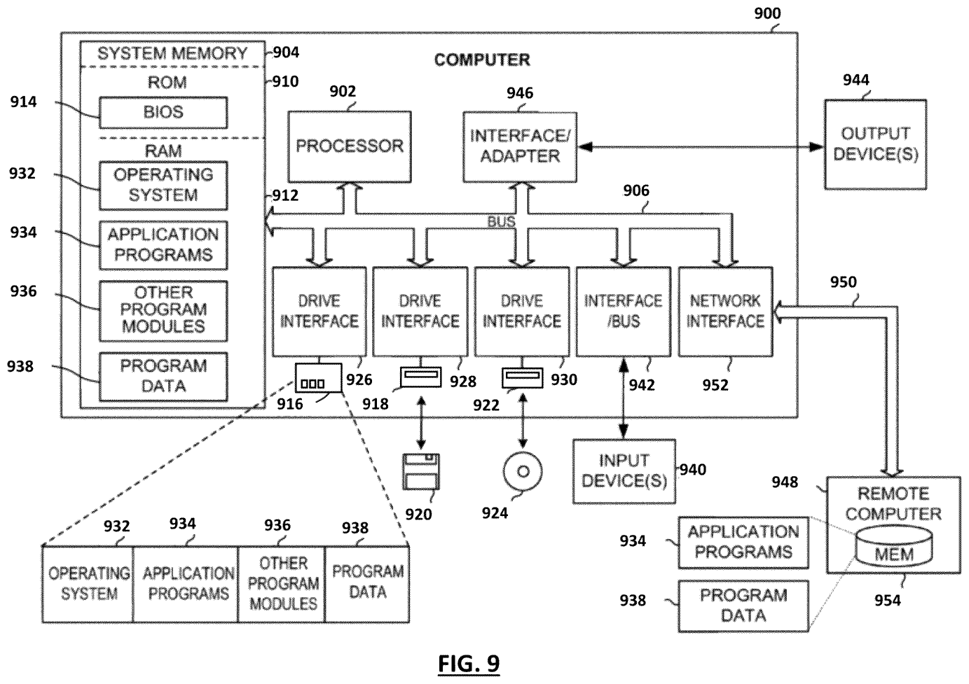

In view of the foregoing structural and functional description, those skilled in the art will appreciate that portions of the embodiments may be embodied as a method, data processing system, or computer program product. Accordingly, these portions of the present embodiments may take the form of an entirely hardware embodiment, an entirely software embodiment, or an embodiment combining software and hardware, such as shown and described with respect to the computer system of FIG. 9. Thus, reference can be made to one or more examples of FIGS. 1-8 in the example of FIG. 9.

In this regard, FIG. 9 illustrates one example of a computer system 600 that can be employed to execute one or more embodiments of the present disclosure. Computer system 900 can be implemented on one or more general purpose networked computer systems, embedded computer systems, routers, switches, server devices, client devices, various intermediate devices/nodes or standalone computer systems. Additionally, computer system 900 can be implemented on various mobile clients such as, for example, a personal digital assistant (PDA), laptop computer, pager, and the like, provided it includes sufficient processing capabilities.

Computer system 900 includes processing unit 902, system memory 904, and system bus 906 that couples various system components, including the system memory 904, to processing unit 902. Dual microprocessors and other multi-processor architectures also can be used as processing unit 902. System bus 906 may be any of several types of bus structure including a memory bus or memory controller, a peripheral bus, and a local bus using any of a variety of bus architectures. System memory 904 includes read only memory (ROM) 910 and random access memory (RAM) 912. A basic input/output system (BIOS) 914 can reside in ROM 912 containing the basic routines that help to transfer information among elements within computer system 900.

Computer system 900 can include a hard disk drive 916, magnetic disk drive 918, e.g., to read from or write to removable disk 920, and an optical disk drive 922, e.g., for reading CD-ROM disk 924 or to read from or write to other optical media. Hard disk drive 916, magnetic disk drive 918, and optical disk drive 922 are connected to system bus 906 by a hard disk drive interface 926, a magnetic disk drive interface 928, and an optical drive interface 930, respectively. The drives and associated computer-readable media provide nonvolatile storage of data, data structures, and computer-executable instructions for computer system 900. Although the description of computer-readable media above refers to a hard disk, a removable magnetic disk and a CD, other types of media that are readable by a computer, such as magnetic cassettes, flash memory cards, digital video disks and the like, in a variety of forms, may also be used in the operating environment; further, any such media may contain computer-executable instructions for implementing one or more parts of embodiments shown and disclosed herein. A number of program modules may be stored in drives and RAM 910, including operating system 932, one or more application programs 934, other program modules 936, and program data 938. In some examples, the application programs 934 can include one or more modules (or block diagrams), or systems, as shown and disclosed herein.

A user may enter commands and information into computer system 900 through one or more input devices 940, such as a pointing device (e.g., a mouse, touch screen), keyboard, microphone, joystick, game pad, scanner, and the like. These and other input devices are often connected to processing unit 902 through a corresponding port interface 942 that is coupled to the system bus, but may be connected by other interfaces, such as a parallel port, serial port, or universal serial bus (USB). One or more output devices 944 (e.g., display, a monitor, printer, projector, or other type of displaying device) is also connected to system bus 906 via interface 946, such as a video adapter.

Computer system 900 may operate in a networked environment using logical connections to one or more remote computers, such as remote computer 948. Remote computer 948 may be a workstation, computer system, router, peer device, or other common network node, and typically includes many or all the elements described relative to computer system 900. The logical connections, schematically indicated at 950, can include a local area network (LAN) and a wide area network (WAN). When used in a LAN networking environment, computer system 900 can be connected to the local network through a network interface or adapter 952. When used in a WAN networking environment, computer system 900 can include a modem, or can be connected to a communications server on the LAN. The modem, which may be internal or external, can be connected to system bus 906 via an appropriate port interface. In a networked environment, application programs 934 or program data 938 depicted relative to computer system 900, or portions thereof, may be stored in a remote memory storage device 954.

Although this disclosure includes a detailed description on a computing platform and/or computer, implementation of the teachings recited herein are not limited to only such computing platforms. Rather, embodiments of the present disclosure are capable of being implemented in conjunction with any other type of computing environment now known or later developed.

Cloud computing is a model of service delivery for enabling convenient, on-demand network access to a shared pool of configurable computing resources (e.g., networks, network bandwidth, servers, processing, memory, storage, applications, virtual machines, and services) that can be rapidly provisioned and released with minimal management effort or interaction with a provider of the service. This cloud model may include at least five characteristics, at least three service models (e.g., software as a service (Saas, platform as a service (PaaS), and/or infrastructure as a service (IaaS)) and at least four deployment models (e.g., private cloud, community cloud, public cloud, and/or hybrid cloud). A cloud computing environment can be service oriented with a focus on statelessness, low coupling, modularity, and semantic interoperability.

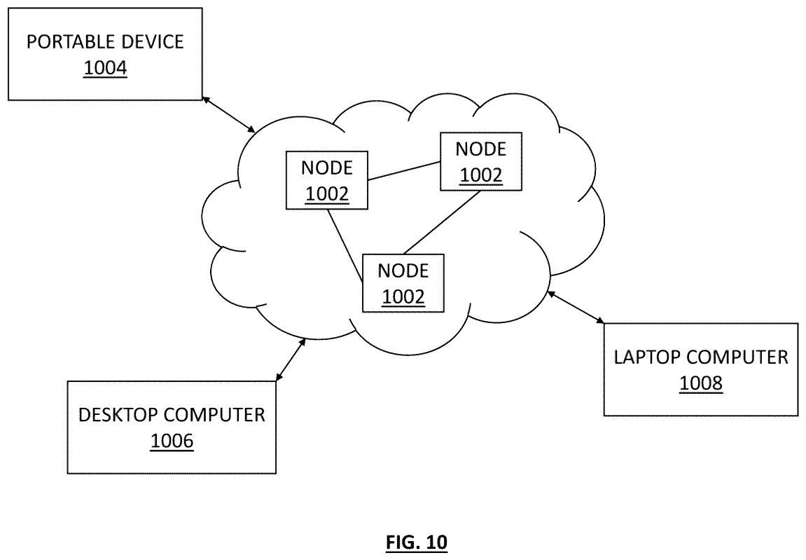

FIG. 10 is an example of a cloud computing environment 1000 that can be used for implementing one or more modules and/or systems in accordance with one or more examples, as disclosed herein. Thus, reference can be made to one or more examples of FIGS. 1-9 in the example of FIG. 10. As shown, cloud computing environment 1000 can include one or more cloud computing nodes 1002 with which local computing devices used by cloud consumers (or users), such as, for example, personal digital assistant (PDA), cellular, or portable device 1004, a desktop computer 1006, and/or a laptop computer 1008, may communicate. The computing nodes 1002 can communicate with one another. In some examples, the computing nodes 1002 can be grouped (not shown) physically or virtually, in one or more networks, such as Private, Community, Public, or Hybrid clouds, or a combination thereof. This allows the cloud computing environment 1000 to offer infrastructure, platforms and/or software as services for which a cloud consumer does not need to maintain resources on a local computing device. The devices 1004-1008, as shown in FIG. 10, are intended to be illustrative and that computing nodes 1002 and cloud computing environment 1000 can communicate with any type of computerized device over any type of network and/or network addressable connection (e.g., using a web browser). In some examples, the one or more computing nodes 1002 are used for implementing one or more examples disclosed herein relating to root-source identification. Thus, in some examples, the one or more computing nodes can be used to implement modules, platforms, and/or systems, as disclosed herein.

In some examples, the cloud computing environment 1000 can provide one or more functional abstraction layers. It is to be understood that the cloud computing environment 1000 need not provide all of the one or more functional abstraction layers (and corresponding functions and/or components), as disclosed herein. For example, the cloud computing environment 1000 can provide a hardware and software layer that can include hardware and software components. Examples of hardware components include: mainframes; RISC (Reduced Instruction Set Computer) architecture based servers; servers; blade servers; storage devices; and networks and networking components. In some embodiments, software components include network application server software and database software.

In some examples, the cloud computing environment 1000 can provide a virtualization layer that provides an abstraction layer from which the following examples of virtual entities may be provided: virtual servers; virtual storage; virtual networks, including virtual private networks; virtual applications and operating systems; and virtual clients. In some examples, the cloud computing environment 1000 can provide a management layer that can provide the functions described below. For example, the management layer can provide resource provisioning that can provide dynamic procurement of computing resources and other resources that are utilized to perform tasks within the cloud computing environment. The management layer can also provide metering and pricing to provide cost tracking as resources are utilized within the cloud computing environment 1000, and billing or invoicing for consumption of these resources. In one example, these resources may include application software licenses. Security provides identity verification for cloud consumers and tasks, as well as protection for data and other resources. The management layer can also provide a user portal that provides access to the cloud computing environment 1000 for consumers and system administrators. The management layer can also provide service level management, which can provide cloud computing resource allocation and management such that required service levels are met. Service Level Agreement (SLA) planning and fulfillment can also be provided to provide pre-arrangement for, and procurement of, cloud computing resources for which a future requirement is anticipated in accordance with an SLA.

In some examples, the cloud computing environment 1000 can provide a workloads layer that provides examples of functionality for which the cloud computing environment 1000 may be utilized. Examples of workloads and functions which may be provided from this layer include: mapping and navigation; software development and lifecycle management; virtual classroom education delivery; data analytics processing; and transaction processing. Various embodiments of the present disclosure can utilize the cloud computing environment 1000.

The present disclosure is also directed to the following exemplary embodiments, which can be practiced in any combination thereof:
Embodiment 1: A combination of claims 1-10
Embodiment 2: A combination of claims 11-20

The present invention may be a system, a method, and/or a computer program product at any possible technical detail level of integration. The computer program product may include a computer readable storage medium (or media) having computer readable program instructions thereon for causing a processor to carry out aspects of the present invention. The computer readable storage medium can be a tangible device that can retain and store instructions for use by an instruction execution device. The computer readable storage medium may be, for example, but is not limited to, an electronic storage device, a magnetic storage device, an optical storage device, an electromagnetic storage device, a semiconductor storage device, or any suitable combination of the foregoing. A non-exhaustive list of more specific examples of the computer readable storage medium includes the following: a portable computer diskette, a hard disk, a random access memory (RAM), a read-only memory (ROM), an erasable programmable read-only memory (EPROM or Flash memory), a static random access memory (SRAM), a portable compact disc read-only memory (CD-ROM), a digital versatile disk (DVD), a memory stick, a floppy disk, a mechanically encoded device such as punch-cards or raised structures in a groove having instructions recorded thereon, and any suitable combination of the foregoing. A computer readable storage medium, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire.

Computer readable program instructions described herein can be downloaded to respective computing/processing devices from a computer readable storage medium or to an external computer or external storage device via a network, for example, the Internet, a local area network, a wide area network and/or a wireless network. The network may comprise copper transmission cables, optical transmission fibers, wireless transmission, routers, firewalls, switches, gateway computers and/or edge servers. A network adapter card or network interface in each computing/processing device receives computer readable program instructions from the network and forwards the computer readable program instructions for storage in a computer readable storage medium within the respective computing/processing device.

Computer readable program instructions for carrying out operations of the present invention may be assembler instructions, instruction-set-architecture (ISA) instructions, machine instructions, machine dependent instructions, microcode, firmware instructions, state-setting data, configuration data for integrated circuitry, or either source code or object code written in any combination of one or more programming languages, including an object oriented programming language such as Smalltalk, C++, or the like, and procedural programming languages, such as the “C” programming language or similar programming languages. The computer readable program instructions may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider). In some embodiments, electronic circuitry including, for example, programmable logic circuitry, field-programmable gate arrays (FPGA), or programmable logic arrays (PLA) may execute the computer readable program instructions by utilizing state information of the computer readable program instructions to personalize the electronic circuitry, in order to perform aspects of the present invention.

Aspects of the present invention are described herein with reference to flowchart illustrations and/or block diagrams of methods, apparatus (systems), and computer program products according to embodiments of the invention. It will be understood that each block of the flowchart illustrations and/or block diagrams, and combinations of blocks in the flowchart illustrations and/or block diagrams, can be implemented by computer readable program instructions.

These computer readable program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks. These computer readable program instructions may also be stored in a computer readable storage medium that can direct a computer, a programmable data processing apparatus, and/or other devices to function in a particular manner, such that the computer readable storage medium having instructions stored therein comprises an article of manufacture including instructions which implement aspects of the function/act specified in the flowchart and/or block diagram block or blocks.

The computer readable program instructions may also be loaded onto a computer, other programmable data processing apparatus, or other device to cause a series of operational steps to be performed on the computer, other programmable apparatus or other device to produce a computer implemented process, such that the instructions which execute on the computer, other programmable apparatus, or other device implement the functions/acts specified in the flowchart and/or block diagram block or blocks.

The flowchart and block diagrams in the Figures illustrate the architecture, functionality, and operation of possible implementations of systems, methods, and computer program products according to various embodiments of the present invention. In this regard, each block in the flowchart or block diagrams may represent a module, segment, or portion of instructions, which comprises one or more executable instructions for implementing the specified logical function(s). In some alternative implementations, the functions noted in the blocks may occur out of the order noted in the Figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware based systems that perform the specified functions or acts or carry out combinations of special purpose hardware and computer instructions.

The terminology used herein is for the purpose of describing particular embodiments only and is not intended to be limiting of the invention. As used herein, for example, the singular forms “a,” “an,” and “the” are intended to include the plural forms as well, unless the context clearly indicates otherwise. It will be further understood that the terms “contains”, “containing”, “includes”, “including,” “comprises”, and/or “comprising,” and variations thereof, when used in this specification, specify the presence of stated features, integers, steps, operations, elements, and/or components, but do not preclude the presence or addition of one or more other features, integers, steps, operations, elements, components, and/or groups thereof. In addition, the use of ordinal numbers (e.g., first, second, third, etc.) is for distinction and not counting. For example, the use of “third” does not imply there must be a corresponding “first” or “second.” Also, as used herein, the terms “coupled” or “coupled to” or “connected” or “connected to” or “attached” or “attached to” may indicate establishing either a direct or indirect connection, and is not limited to either unless expressly referenced as such. Furthermore, to the extent that the terms “includes,” “has,” “possesses,” and the like are used in the detailed description, claims, appendices and drawings such terms are intended to be inclusive in a manner similar to the term “comprising” as “comprising” is interpreted when employed as a transitional word in a claim. The term “based on” means “based at least in part on.” The terms “about” and “approximately” can be used to include any numerical value that can vary without changing the basic function of that value. When used with a range, “about” and “approximately” also disclose the range defined by the absolute values of the two endpoints, e.g. “about 2 to about 4” also discloses the range “from 2 to 4.” Generally, the terms “about” and “approximately” may refer to plus or minus 5-10% of the indicated number.

What has been described above include mere examples of systems, computer program products and computer-implemented methods. It is, of course, not possible to describe every conceivable combination of components, products and/or computer-implemented methods for purposes of describing this disclosure, but one of ordinary skill in the art can recognize that many further combinations and permutations of this disclosure are possible. The descriptions of the various embodiments have been presented for purposes of illustration, but are not intended to be exhaustive or limited to the embodiments disclosed. Many modifications and variations will be apparent to those of ordinary skill in the art without departing from the scope and spirit of the described embodiments.

The invention claimed is:

1. A method for optimizing well placement for a hydrocarbon reservoir, the method comprising:
receiving a set of parameters and constraints as input;
executing an optimization algorithm upon the set of parameters and constraints to initiate a set of dynamic simulations wherein the dynamic simulations capture multiple realizations, to test a plurality of different well locations to produce a first set of outcomes corresponding to well count and well locations;
evaluating the first set of outcomes;
executing multiple iterations of the dynamic simulations and evaluating each corresponding set of outcomes until a desired outcome is achieved; and
executing an anti-collision algorithm wherein the algorithm checks for potential collisions with one or more existing trajectories inside and outside the hydrocarbon reservoir.

2. The method of claim 1 wherein the desired outcome avoids zones where potential collisions with one or more existing trajectories inside and outside the hydrocarbon reservoir are located.

3. The method of claim 1 wherein the multiple realizations comprise an ensemble of probability models, or high, mid, and low scenarios, or any combination thereof.

4. The method of claim 1 further comprising optimizing well count and well location based on the outcomes from the dynamic simulations.

5. The method of claim 1 wherein the set of parameters and constraints further comprises multiple subsurface static models as input.

6. The method of claim 1 wherein the set of parameters and constraints further comprises multiple subsurface dynamic models as input.

7. The method of claim 1 wherein the set of parameters and constraints further comprises surface constraints and subsurface constraints.

8. The method of claim 7 wherein the surface constraints include surface pad locations.

9. The method of claim 1 wherein the desired outcome comprises a maximized net present value with an optimal well count and well location.

10. The method of claim 1 further comprising defining a cost model and objective function, wherein the desired outcome further optimizes economic value through the cost model.

11. A computer-readable storage medium containing instructions for optimizing well placement for a hydrocarbon reservoir, wherein the instructions, when executed by a processor, cause the processor to perform operations comprising:
receiving a set of parameters and constraints as input;
executing an optimization algorithm upon the set of parameters and constraints to initiate a set of dynamic simulations wherein the dynamic simulations capture multiple realizations, to test a plurality of different well locations to produce a first set of outcomes corresponding to well count and well locations;
evaluating the first set of outcomes;
executing multiple iterations of the dynamic simulations and evaluating each corresponding set of outcomes until a desired outcome is achieved; and
executing an anti-collision algorithm wherein the algorithm checks for potential collisions with one or more existing trajectories inside and outside the hydrocarbon reservoir.

12. The computer-readable storage medium of claim 11 wherein the desired outcome avoids zones where potential collisions with one or more existing trajectories inside and outside the hydrocarbon reservoir are located.

13. The computer-readable storage medium of claim 11 wherein the multiple realizations comprise an ensemble of probability models, or high, mid, and low scenarios, or any combination thereof.

14. The computer-readable storage medium of claim 11, the set of instructions further causing the machine to perform the steps of optimizing well count and well location based on the outcomes from the dynamic simulations.

15. The computer-readable storage medium of claim 11 wherein the set of parameters and constraints further comprises multiple subsurface static models as input.

16. The computer-readable storage medium of claim 11 wherein the set of parameters and constraints further comprises multiple subsurface dynamic models as input.

17. The computer-readable storage medium of claim 11 wherein the set of parameters and constraints further comprises surface constraints and subsurface constraints.

18. The computer-readable storage medium of claim 17 wherein the surface constraints include surface pad locations.

19. The computer-readable storage medium of claim 11 wherein the desired outcome comprises a maximized net present value with an optimal well count and well location.

20. The computer-readable storage medium of claim 11, the set of instructions further causing the machine to perform the steps of defining a cost model and objective function, wherein the desired outcome further optimizes economic value through the cost model.
